(19) United States
(12) Patent Application Publication
(10) Pub. No.: US 2012/0113573 A1
(43) Pub. Date: May 10, 2012

(54) CABLE ASSEMBLY ADAPTED FOR POWER AND SIGNAL TRANSMITTING

(75) Inventors: DAVID KO, Fullerton, CA (US); CHANG-MAO LI, Kunshan (CN)

(73) Assignee: HON HAI PRECISION INDUSTRY CO., LTD., New Taipei (TW)

(21) Appl. No.: 13/290,151

(22) Filed: Nov. 7, 2011

(30) Foreign Application Priority Data
Nov. 5, 2010 (CN) 201010533124.8

(51) Int. Cl. H05K 7/00; H01R 3/00

(52) U.S. Cl. 361/679.01; 439/489

(57) ABSTRACT

A cable assembly (100) includes at least one connector (1) for transmitting power signal or optical signal; a cover (3) holding the connector; a cable electrically or optically connected with the connector; and a switch device (5) located inside the cover, the switch device includes a switch member, a LED, and a button partially exposed outward of the cover; wherein when the button is pressed to actuate the switch member and the LED is lighted to emit light through the button.

### BACKGROUND OF THE INVENTION

1. Field of the Invention

The present invention relates to a cable assembly, especially to a cable assembly adapted for power and signal transmitting.

2. Description of Related Art

CN patent No. 200820303305.X issued on Oct. 28, 2009 to Su et al. discloses a cable assembly which comprises a first cable connector, a circuit board installed inside the first cable connector, a shielding shell surrounded outside the circuit board and an insulating shell positioned outside the shielding shell; wherein, the end of the circuit board is connected with two cables penetrating out of the shielding shell, the other ends of the two cables are respectively connected with a second cable connector being in accordance with the displayport standard and a third cable connector being in accordance with the USB standard. The cable assembly has the improved structure and is provided with an additional USB connector for supplying power source.

However, there is no switch device applied to the cable assembly to control power or signal transmitting. Therefore, it is inconvenient for using the cable assembly, sometimes.

Hence, a cable assembly with control means is required to overcome the problems of the prior art.

### SUMMARY OF THE INVENTION

An object of the present invention is to provide a cable assembly with switch device.

Accordingly, to achieve above-mentioned object, a cable assembly comprises at least one connector for transmitting power signal or optical signal; a cover holding the connector; a cable electrically or optically connected with the connector; and a switch device located inside the cover, the switch device includes a switch member, a LED, and a button partially exposed outward of the cover; wherein when the button is pressed to actuate the switch member and the LED is lighted to emit light through the button.

The detailed features of the present invention will be apparent in the detailed description with appropriate reference to the accompanying drawings.

### BRIEF DESCRIPTION OF THE DRAWINGS

FIG. 1 is a perspective view of a cable assembly in accordance with the present invention;

FIG. 2 is similar to FIG. 1, with a dustproof cap mounted to a port of the cable assembly;

FIG. 3 is an exploded, perspective view of the cable assembly;

FIG. 4 is similar to FIG. 3, but viewed from other aspect;

FIG. 5 is a partially assembled view of FIG. 3;

FIG. 6 is a cross-section view of the FIG. 2 taken along a line 6-6;

FIG. 7 is an exploded, perspective view of a first connector in FIG. 3;

FIG. 8 is a cross-section view of the first connector taken along a line 8-8;

FIG. 9 is an exploded, perspective view of a second connector in FIG. 3;

FIG. 10 is similar to FIG. 9, but viewed from other aspect;

FIG. 11 is an exploded, perspective view of a switch device in FIG. 3;

FIG. 12 is a perspective view of a receptacle connector assembly for mating with the cable assembly;

FIG. 13 is an exploded, perspective view of the receptacle connector assembly;

FIG. 14 is an exploded, perspective view of a second receptacle connector in FIG. 13;

FIG. 15 is a front side view of the cable assembly;

FIG. 16 is a front side view of the receptacle connector assembly; and

FIG. 17 shows the cable assembly and the receptacle connector assembly aligning with each other for mating.

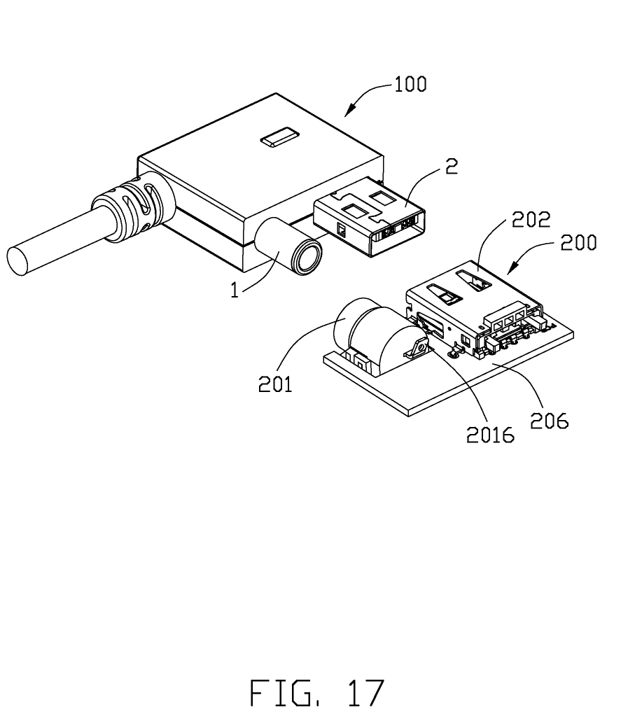

### DETAILED DESCRIPTION OF THE INVENTION

Reference will now be made in detail to the preferred embodiment of the present invention.

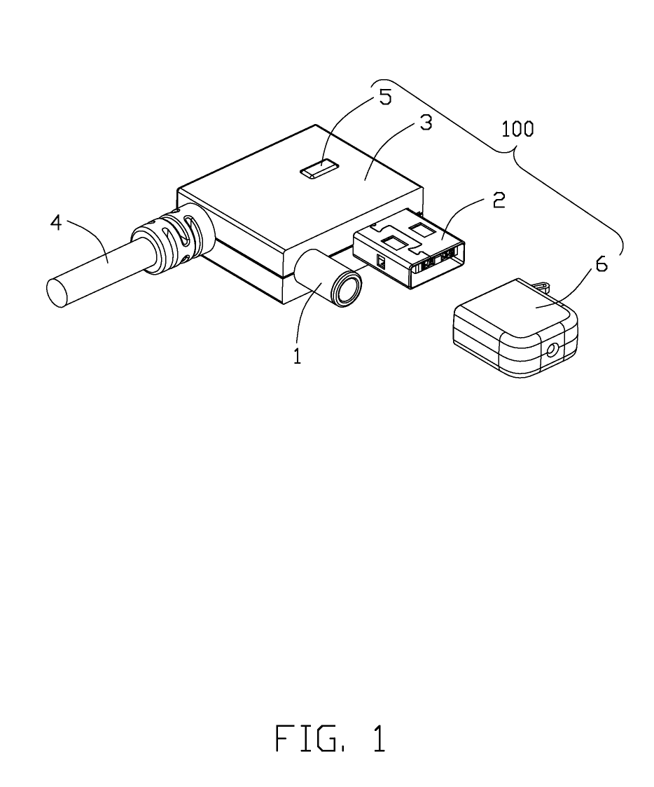

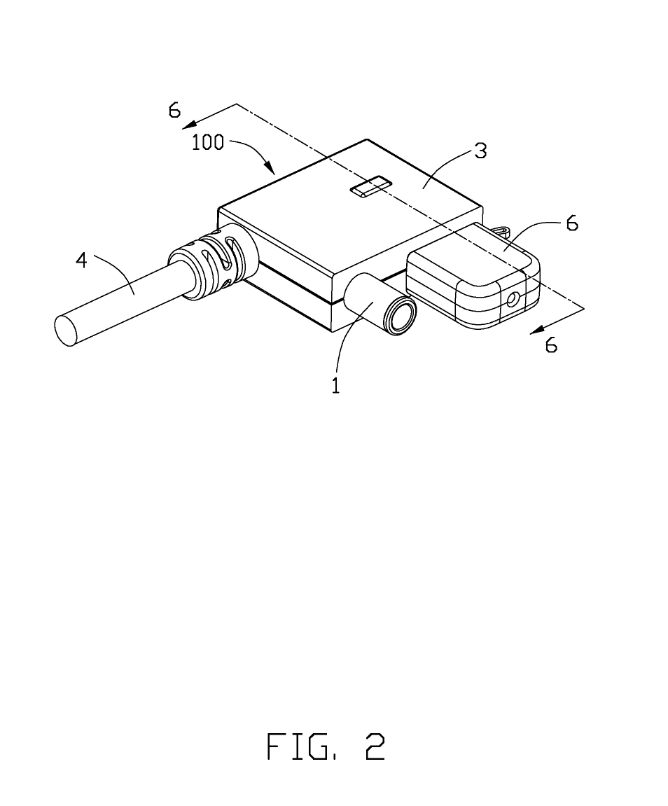

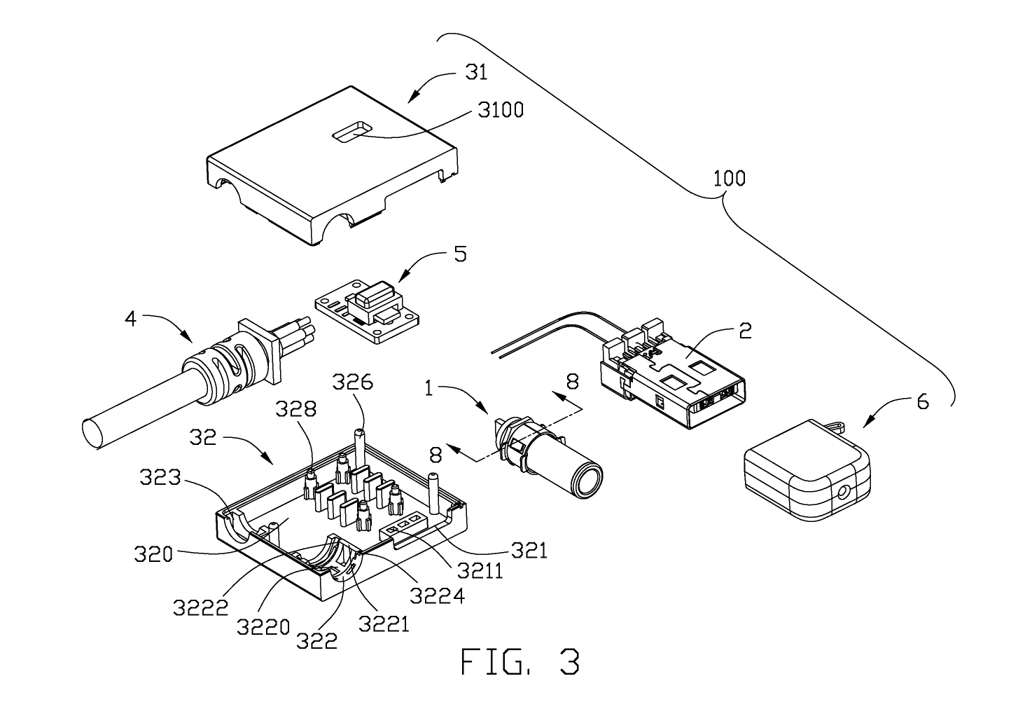

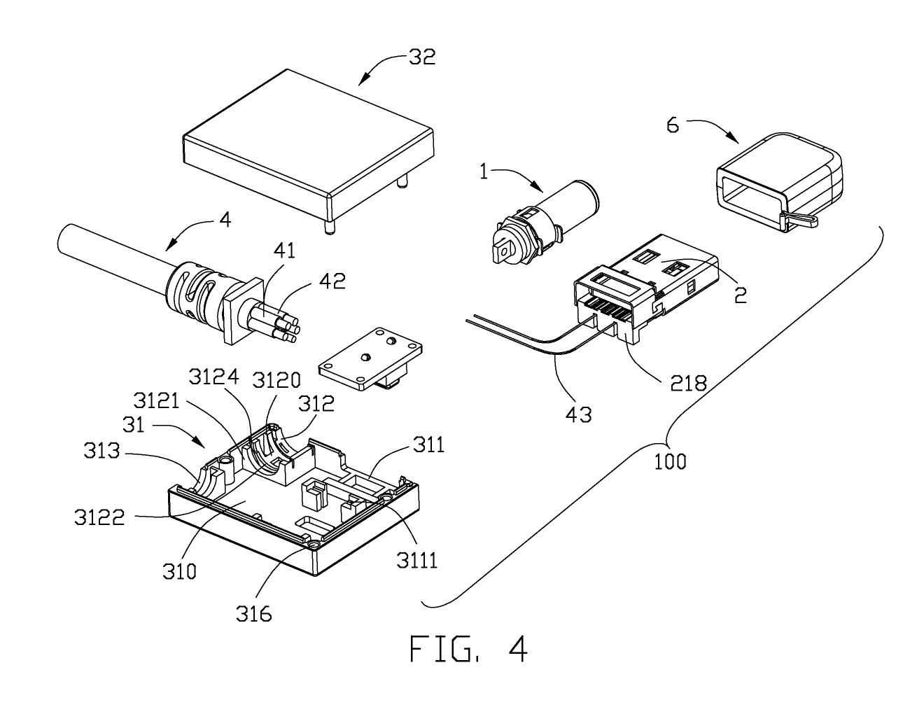

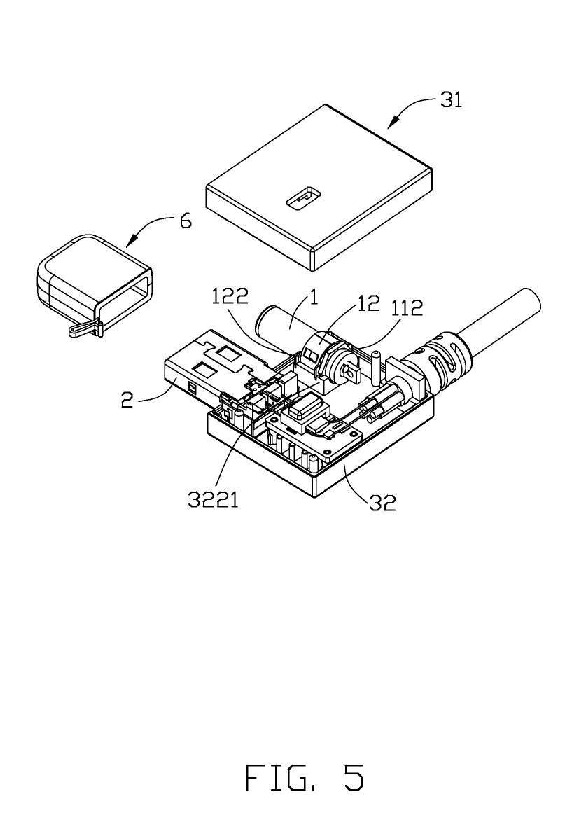

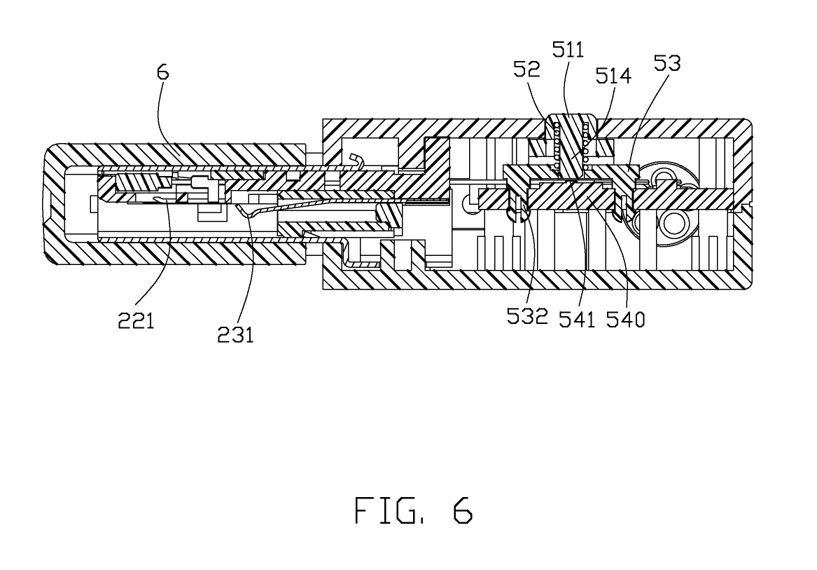

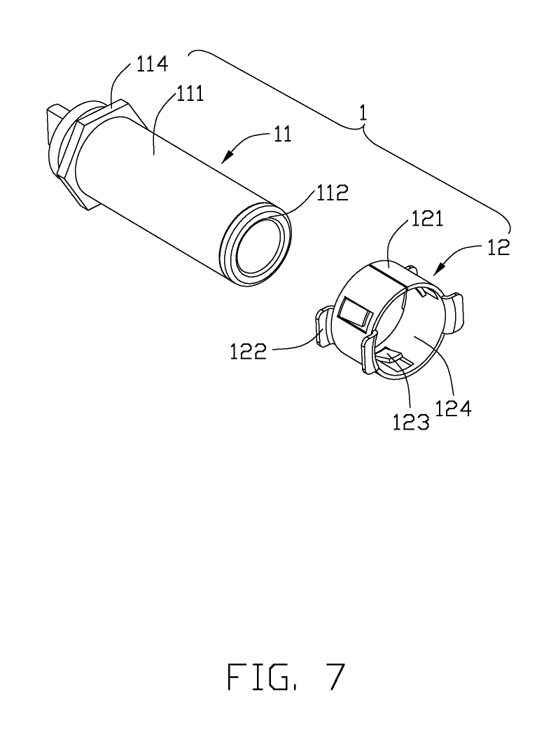

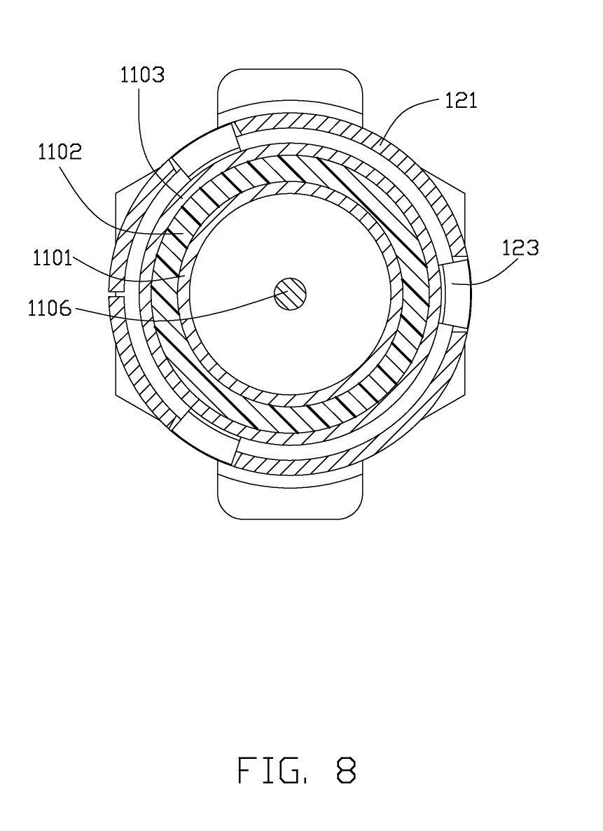

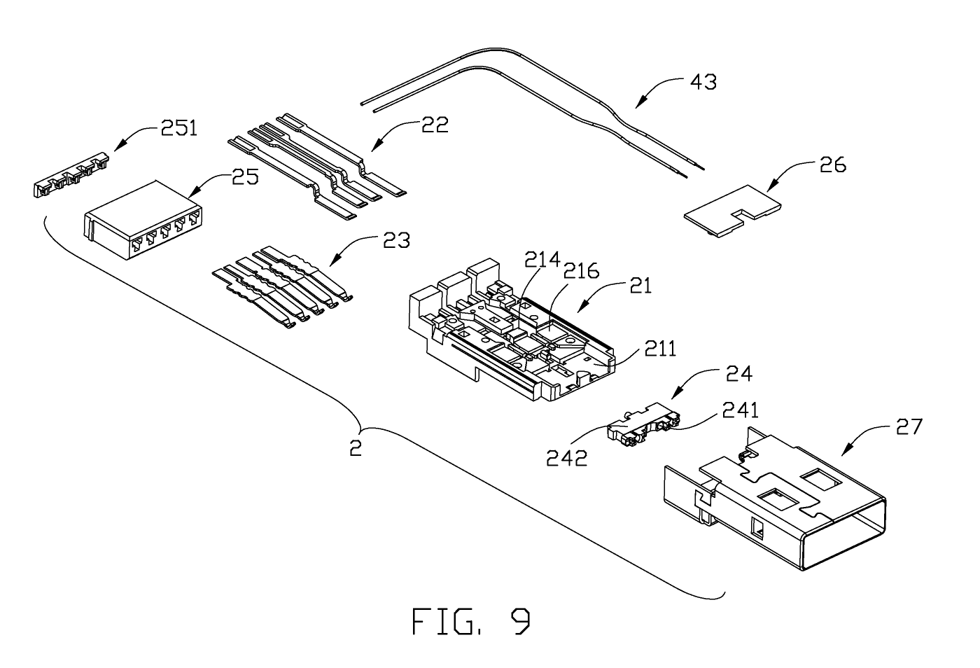

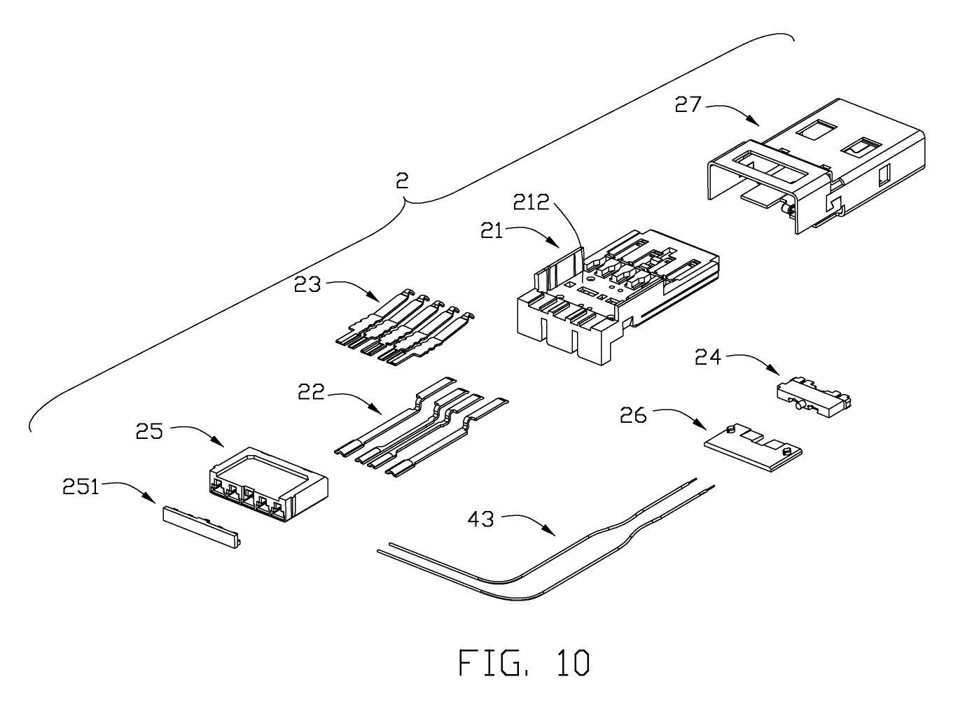

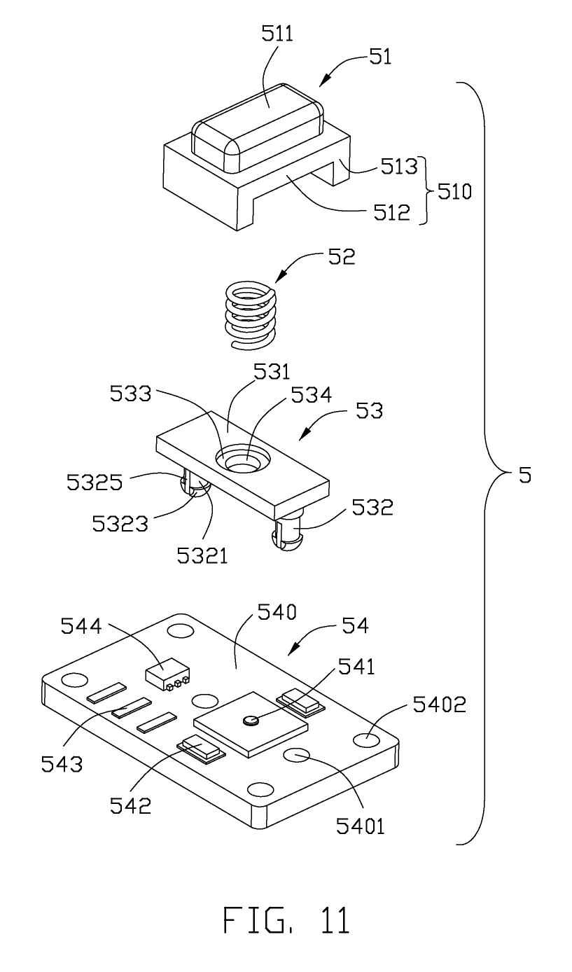

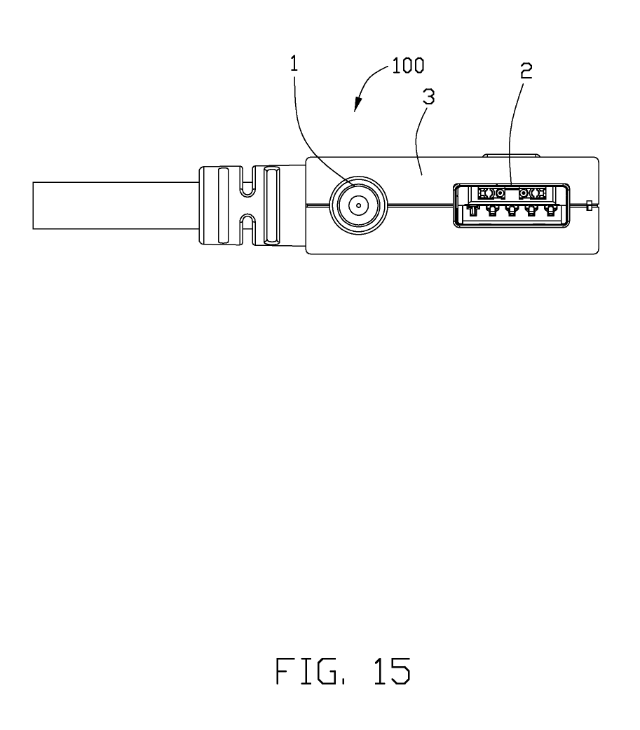

Referring to FIGS. 1-11 and 15, a cable assembly 100 in accordance with the present invention comprises a first connector 1, a second connector 2, a cover 3, a cable 4, a switch device 5 and a dustproof cap 6. The first connector 1 and the second connector 2 are arranged in juxtaposed manner and held by the cover 3.

The first connector 1 is a power connector, and it transmits DC power in the present invention. The first connector 1 includes an elongated cylindrical shaped body portion 111 with a circular mating port 112 located at a front segment thereof and a hexagonal shaped flange 114 located at a back segment thereof. The body portion 111 has a cylindrical shape insulative layer 1102, a positive contact 1101 attached to an inner of the body portion 111 and a negative contact 1103 attached to a peripheral of the body portion 111. Thus, the positive contact 1101 and the negative contact 1103 are coaxially disposed and insulated from each other by an insulative layer 1102 therebetween. In addition, there is detective contact 1106 arranged in a center of the body portion 111 and extends along an axial direction.

The first connector 1 further has a ferrule 12 mounted to the back segment of the body portion 111. The ferrule 12 includes a circular shaped main portion 121 enclosing a hollow 124 therein. The hollow 124 is larger than the body portion 111 but smaller than the flange 114. Therefore, the body portion 111 may active or floatable inside the hollow 124 along a radial direction, but not escape from the hollow 124 along an axial direction by stopping of the flange 112. There are two pairs of retaining tabs 122 respectively formed at a front and a back edges of the main portion 121 and oppositely arranged regarding to the axial direction. In addition, there are several spring tabs 123 formed on the main portion 121 and extending into the hollow 124. In present embodiment, there are three spring tabs 123 symmetrically arranged along circumferential direction of the hollow 124. The ferrule 12 is assembled to the body portion 111, with the spring tabs 123 pressing onto the body portion 111. Furthermore, the body portion 111 and the ferrule 112 are coaxially disposed and a distance or gap along the radial direction therebetween is about 0.3 mm.

The second connector 2 is adapted for transmitting signal. The second connector 2 includes an insulative housing 21, a set of first pins 22 mounted to the insulative housing 21, a set of second pins 23 combined with a contact seat 25 and assembled to the insulative housing 21; in addition, a positioning member 251 is attached to a back segment of the contact seat 25 to secure the second pins 23. The insulative housing 21 defines a mounting cavity 212 in a back segment thereof to accommodate the contact seat 25. The first pins 22 and the second pins 23 arranged offset from each other along a front-to-back direction.

The second connector 2 further includes an optical module 24 accommodated in a cavity 211 located in a front segment of the insulative housing 21. The optical module 24 has a number of lenses 241 arranged in a row and enclosed in a retainer 242. The cable 4 has several fibers 43 which pass through corresponding grooves 214 in the insulative housing 21 and extend into the cavity 211 to couple with the lenses 241. A retaining board 26 is positioned in a depression 216 of the insulative housing 21 so as to confine the optical module 24 and the fibers 43.

The cover 3 includes a top cover 31 and a bottom cover 32 assembled together.

The top cover 31 defines a first receiving space 310 which communicates with an exterior via a first semicircular shaped opening 312 and a first rectangular shaped opening 311 in a front side of the top cover 31 and a first semicircular shaped outlet 313 in a lateral side of the top cover 31. There is a first upper positioning portion 3121 located adjacent to and behind the first semicircular shaped opening 312. The first upper positioning portion 3121 defines a semicircular shaped mounting recess 3120 aligning with and communicating with the first semicircular opening 312. There is a slot 3122 located in a back segment of the mounting recess 3120. Two pairs of slits 3124 are located in lateral sides of the mounting recess 3120, one pair of the slits 3124 are disposed in front of and adjacent to the slot 3122, and the other pair of slits 3124 are disposed behind and proximate the first semicircular shaped opening 312. The ferrule 12 is accommodated in the mounting recess 3120, with the retaining tabs 122 engaged with the slits 3124. The flange 114 is accommodated in the slot 3122. There is a second upper positioning portion 3111 located in the receiving space 310 and behind the first rectangular shaped opening 311. There is a window 3100 defined in a top wall of the top cover 31 and the window 3100 further communicates with the receiving space 310. In addition, there are a number positioning holes 316 located in the receiving space 310 and adjacent to the lateral sides of the top cover 31.

The bottom cover 32 defines a second receiving space 320 which communicates with exterior via a second semicircular shaped opening 322 and a second rectangular shaped opening 321 in a front side of the bottom cover 32 and a semicircular shaped outlet 323 in a lateral side of the bottom cover 32. There is a first lower positioning portion 3221 located adjacent to and behind the second semicircular shaped opening 322. The first lower positioning portion 3221 defines a semicircular shaped mounting recess 3220 aligning with and communicating with the second semicircular opening 322. There is a slot 3222 located in a back segment of the mounting recess 3220. Two pairs of slits 3224 are located in lateral sides of the mounting recess 3220, one pair of the slits 3224 are disposed in front of and adjacent to the slot 3222, and the other pair of slits 3224 are disposed behind and proximate the second semicircular shaped opening 322. The ferrule 12 is accommodated in the mounting recess 3220, with the retaining tabs 122 engaged with the slits 3224. The flange 114 is accommodated in the slot 3222. There is a second lower positioning portion 3211 located in the second receiving space 320 and behind the second rectangular shaped opening 321. In addition, there are a number positioning posts 326 located in the receiving space 320 and adjacent to the lateral sides of the bottom cover 32.

The switch device 5 includes a button 51, a spring 52, a supporting member 53 and a PCBA (printed circuit board assembly) 54.

The button 51 includes a main portion 510 and head portion 511 formed on a top side of the main portion 510. The main portion 510 includes a platform 512, two legs 513 extending downwardly from lateral sides of the platform 512 and a post 514 projecting downwardly from a middle of a bottom surface of the platform 512. The post 514 is disposed between the two legs 513 and longer than the two legs 513 along a up-to-down direction. The button 51 is made of transparent material and therefore light may emit or pass therethrough. The spring 52 is a coil spring and mounted to the post 514.

The supporting member 53 includes a board 531, two latching arms 532 extending downwardly from the board 531 and spaced apart from each other. There is a blind positioning cavity 533 located in the board 531 and a through hole 534 further defined in the positioning cavity 533. The positioning cavity 533 and the through hole 534 are circular shape, and the positioning cavity 533 is larger than the through hole 534. A lower end of the spring 52 is accommodated in the positioning cavity 533. The post 514 can pass through the through hole 534. There is a slot 5325 defined in the latching arm 532 to separate it into two deformable sub-arms 5321. Each sub-arm 5321 has an enlarged free end 5323.

The PCBA 54 includes a circuit substrate 540, a switch member 541 mounted to the circuit substrate 540, two LEDs (Light emitting diode) 542 mounted to the circuit substrate 540 and disposed at opposite sides of the switch member 541. Three conductive pads 543 are formed on a lateral segment of the circuit substrate 540. There is circuit protective element 544 mounted to the circuit substrate 540. Two first positioning holes 5401 located in the circuit substrate 540 and disposed in front of and behind the switch member 541. Four second positioning holes 5402 are located in four corners of the circuit substrate 540.

The circuit substrate 540 is accommodated in the second receiving space 320 of the bottom cover 32, with four standoffs 328 of the bottom cover 32 respectively inserted into the four second positioning holes 5402 of the circuit substrate 540. The supporting member 53 is assembled to the circuit substrate 540, with the latching arms 532 inserted into the first positioning holes 5401, the enlarged free end 5323 abutting a bottom surface of the circuit substrate 540, the board 531 disposed above the a switch member 541 and the through hole 534 aligning with the switch member 541. The button 51 is assembled to the spring member 53, with the platform 512 disposed above and crossing with the board 531, the two legs 513 disposed at opposite sides of the board 531 and located above and proximate to the two LEDs 542. The spring 52 is arranged between the button 51 and the supporting member 53, the post 514 through the spring 52 and entering the through hole 534 so as to actuate or touch the switch member 541. The top cover 31 is assembled to the bottom cover 32, with the head portion 511 exposed outward via the window 3100 and the main portion 510 against a bottom surface of the top wall of the top cover 31.

The cable 4 also includes two first wires 41, three second wires 42, besides the fibers 43. The first wires 41 are electrically connected to the positive contact 1101 and a negative contact 1103 of the first connector 1 and used for transmitting electricity. The second wires 42 are respectively connected to the conductive pads 543 of the PCBA 54 and further electrically connected with the switch member 541 by the circuit substrate 540. In addition, the cable 4 may includes other wires (not shown) connected with first pins 22 and the second pins 23.

The button 51 is pressed and the post 514 moves towards and actuates the switch member 541 so as to switch on a corresponding circuit of the PCBA 54 so as to start transmitting of the cable assembly 100, and the LEDs 542 is lighted and light emits or passes through the button 51, and user may observe working status of the cable assembly 100.

The first connector 1 and the second connector 2 are mounted to the cover 3. The ferrule 12 is fixed to the mounting recess 3120 of the first upper positioning portion 3121 and the mounting recess 3220 of the first lower positioning portion 3221, while the back segment of the body portion 111 is floatably mounted to the ferrule 12, and the flange 114 is received in the slots 3122, 3222; therefore, the first connector 1 are movably or floatably with regarding to the cover 3 along the radial direction which perpendicular to a mating direction. The second connector 2 is securely positioned between the second upper positioning portion 3111 and the second lower positioning portion 3211.

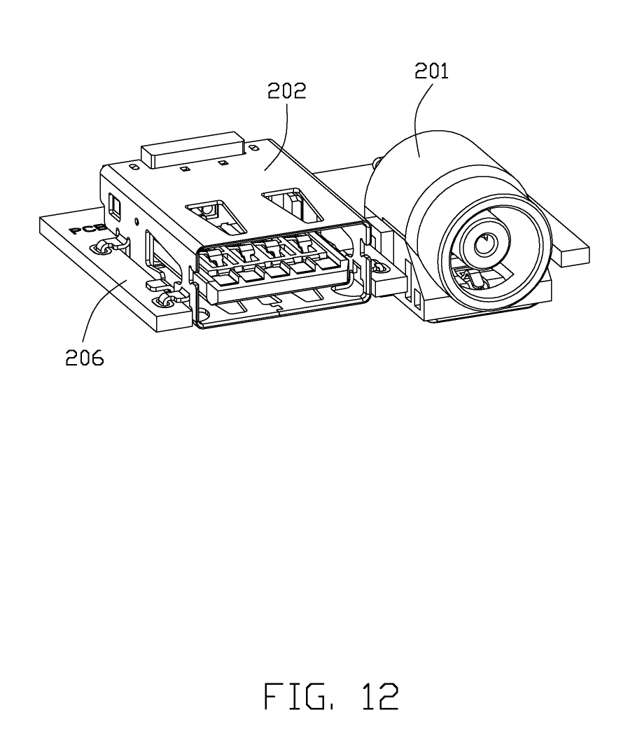

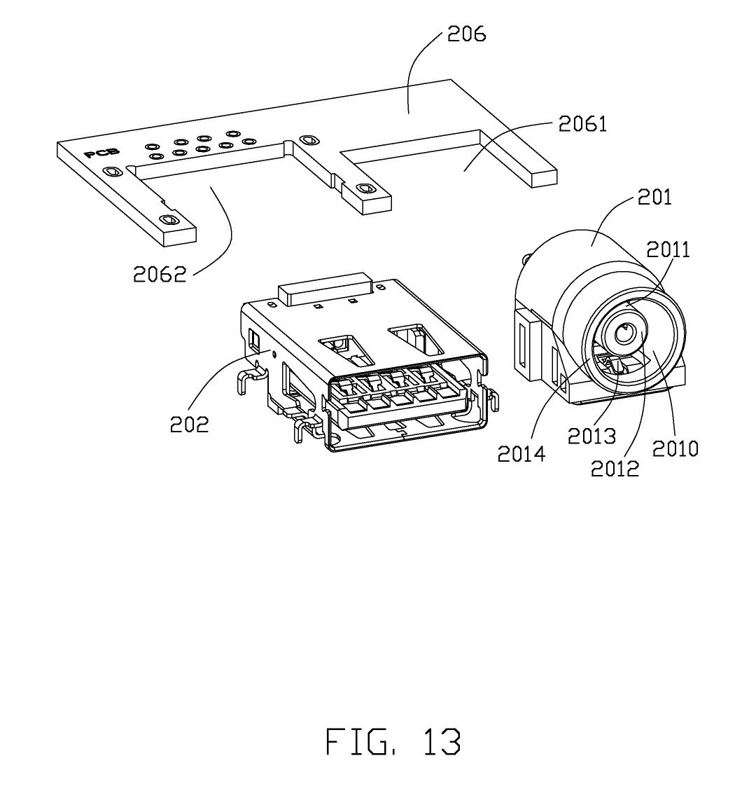

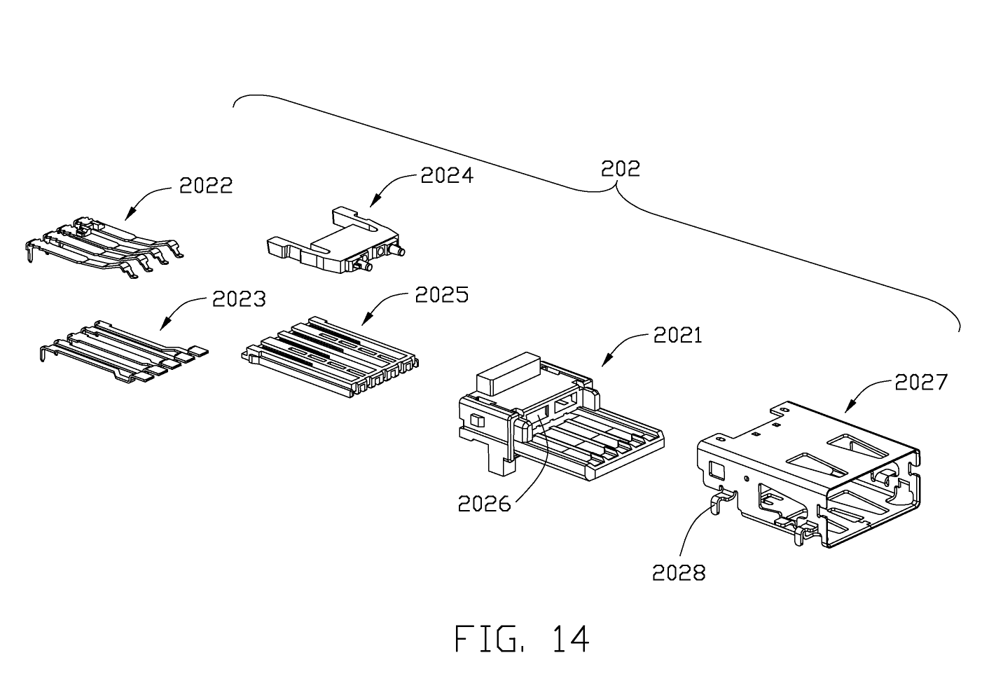

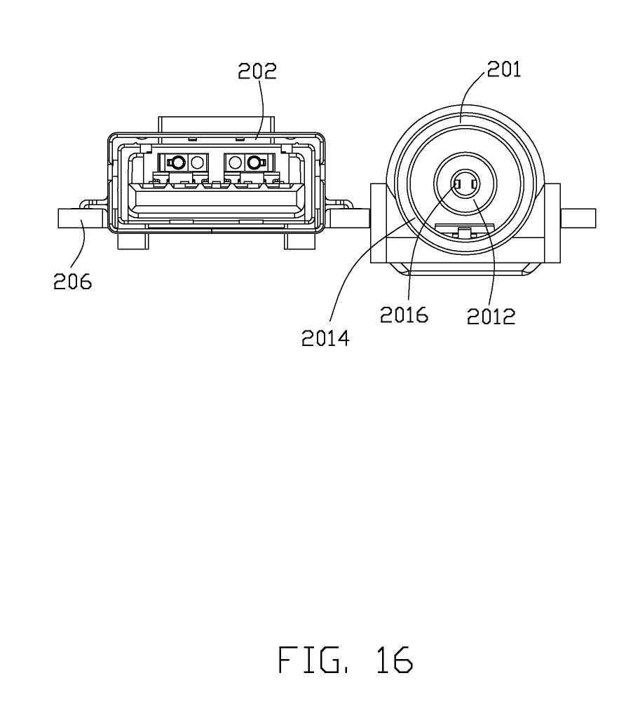

Referring to FIGS. 12, 13, 14 and 16, a receptacle connector assembly 200 includes a first receptacle connector 201, a second receptacle connector 202 mounted to a printed circuit board 206.

The first receptacle connector 201 is used for transmitting electricity and has a circular shaped port 2010 for mating with the first connector 1. The first receptacle connector 201 includes a cylindrical shaped inner insulator 2012 and a cylindrical shaped outer insulator 2014 arranged in coaxial manner. The inner insulator 2012 is enclosed in the outer insulator 2014. There is a positive terminal 2011 attached to an external surface of the inner insulator 2012 and a negative terminal 2013 combined with the outer insulator 2014 and further extending into the port 2010. In addition, there is a detective terminal 2016 located in the inner insulator 2012.

The second receptacle connector 202 is adapted for transmitting signal. The second receptacle connector 202 includes an insulated housing 2021, a set of first contacting pins 2022 and a set of second contacting pins 2023 mounted to the insulated housing 2021. There is an insulative spacer 2025 disposed between the first contacting pins 2022 and the second contacting pins 2023. The second receptacle connector 202 further includes an optical module 2024 accommodated in a recess 2026 located in a back segment of the insulated housing 2021. There is a metallic shell 2027 enclosing the insulated housing 2021. The metallic shell 2027 has several board locking portions 2028 formed at lateral sides thereof.

The printed circuit board 206 defines a first cutout 2061 and a second cutout 2062 arranged in juxtaposed manner. The first receptacle connector 201 is mounted to the first cutout 2061, and the second receptacle connector 202 is mounted to the second cutout 2062.

While a preferred embodiment in accordance with the present invention has been shown and described, equivalent modifications and changes known to persons skilled in the art according to the spirit of the present invention are considered within the scope of the present invention as described in the appended claims.

What is claimed is:

1. A cable assembly, comprising:
at least one connector for transmitting power signal or optical signal;
a cover holding the connector;
a cable electrically or optically connected with the connector; and
a switch device located inside the cover, the switch device includes a switch member, an LED, and a button partially exposed outward of the cover;
wherein
when the button is pressed to actuate the switch member, the LED is lighted to emit light through the button.

2. The cable assembly as claimed in claim 1, wherein the button is made of transparent material.

3. The cable assembly as claimed in claim 1, wherein the switch device further includes a circuit substrate, and the switch member and the LED are mounted to the circuit substrate.

4. The cable assembly as claimed in claim 3, wherein there is supporting member mounted to the circuit substrate and disposed above the switch member.

5. The cable assembly as claimed in claim 4, wherein the supporting member includes a board and at least one latching arm extending downwardly from the board.

6. The cable assembly as claimed in claim 5, wherein the board defines a through hole aligning with the switch member.

7. The cable assembly as claimed in claim 5, wherein the latching arm has two deformable sub-arms, and each sub-arm has an enlarged free end.

8. The cable assembly as claimed in claim 7, wherein there is a positioning hole located in the circuit substrate, and the latching arm is inserted into the positioning hole and the enlarged free end abuts against a bottom surface of the circuit substrate.

9. The cable assembly as claimed in claim 6, wherein the button includes a main portion and a head portion formed on the main portion.

10. The cable assembly as claimed in claim 9, wherein there is a window defined in a top wall of the cover, and the head portion of the button is exposed outward via the window and the main portion is against a bottom surface of the top wall.

11. The cable assembly as claimed in claim 9, wherein there is a post projecting downwardly from a bottom surface of the main portion and capable of passing through the through hole to touch the switch member.

12. The cable assembly as claimed in claim 11, wherein there is a coil spring assembled to the post.

13. A cable assembly, comprising:
a first connector for connecting with first type of wires and transmitting power;
a second connector for connecting with second type of wires and transmitting signal;
a cover including a top cover and a bottom cover assembled together to hold the first connector and the second connector; and
a switch device located inside the cover, the switch device including a PCBA with a switch member and at least one LED, a button being accessible from exterior and capable of actuating the switch member.

14. The cable assembly as claimed in claim 13, wherein the button includes a main portion and a head portion formed on the button, and the head portion extends into a window defined in a top wall of the top cover and the main portion abuts against a bottom surface of the top wall.

15. The cable assembly as claimed in claim 14, wherein the main portion of the button includes a platform and two legs extending downwardly from lateral sides of the platform.

16. The cable assembly as claimed in claim 15, wherein the button is made of transparent material and the LED is disposed under the leg.

17. The cable assembly as claimed in claim 15, wherein there is post extending downwardly from the platform for actuating the switch member.

18. The cable assembly as claimed in claim 17, wherein the post is longer than the two legs.

19. A cable connector assembly comprising:
a case defining a cavity surrounded by a plurality of sides including a mating port side and a cable extension side;
first and second connectors side by side disposed on the mating port side, the first connector defining electrical and optical signal transmission paths while the second connector defining a power transmission path;
a printed circuit board extending along a plane perpendicular to said sides and located right behind the first connector in the cavity with thereon a switch equipped with an LED for indication of status, said switch being moveable in a direction perpendicular to said plane; and
a round cable extending into the cavity via said cable extension side with corresponding wires and fibers initially occupying a portion of the cavity right behind the second connector and successively electrically connected to the connectors.

20. The cable connector assembly as claimed in claim 19, wherein the cable extension side is essentially transverse to the mating port side.
